(19) United States
(12) Patent Application Publication
(10) Pub. No.: US 2025/0350699 A1
(43) Pub. Date: Nov. 13, 2025

(54) IMAGE DRAWING APPARATUS AND DRIVING METHOD FOR IMAGE DRAWING APPARATUS

(71) Applicant: FUJIFILM Corporation, Tokyo (JP)

(72) Inventors: Shinichiro SONODA, Kanagawa (JP); Hirotoshi YOSHIZAWA, Kanagawa (JP); Nobuya TANAKA, Kanagawa (JP)

(73) Assignee: FUJIFILM Corporation, Tokyo (JP)

(21) Appl. No.: 19/277,011

(22) Filed: Jul. 22, 2025

Related U.S. Application Data
(63) Continuation of application No. PCT/JP2023/043907, filed on Dec. 7, 2023.

(30) Foreign Application Priority Data
Feb. 3, 2023 (JP) 2023-015628

(51) Int. Cl. H04N 1/028

(52) U.S. Cl. CPC H04N 1/0283; H04N 1/02825

(57) ABSTRACT

The image drawing apparatus includes a light source and a processor that controls operations of a first actuator and a second actuator to scan a surface with a light beam reflected by a reflecting surface. The processor estimates a scanning trajectory of the light beam on the surface to be scanned by using a first deflection angle estimation function that is a function of time for the first deflection angle and that takes into account a temporal variation of the first deflection angle depends on the second deflection angle, and a second deflection angle estimation function that is a function of time for the second deflection angle and that takes into account a temporal variation of the second deflection angle depends on the first deflection angle, and causes the light source to emit the light beam in correspondence with the estimated scanning trajectory and the image information.

### CROSS-REFERENCE TO RELATED APPLICATIONS

This application is a continuation application of International Application No. PCT/JP2023/043907, filed Dec. 7, 2023, the disclosure of which is incorporated herein by reference in its entirety. Further, this application claims priority from Japanese Patent Application No. 2023-015628, filed on Feb. 3, 2023, the disclosure of which is incorporated herein by reference in its entirety.

### BACKGROUND

### 1. Technical Field

The technology of the present disclosure relates to an image drawing apparatus and a driving method for the image drawing apparatus.

### 2. Description of the Related Art

A micromirror device (also referred to as a microscanner) is known as one of micro electromechanical systems (MEMS) devices manufactured using the silicon (Si) microfabrication technique. Since an optical scanning device comprising the micromirror device is small and has low power consumption, it is expected to have a range of applications in an image drawing apparatus such as a laser display or a laser projector.

In the micromirror device, a mirror portion is formed to be oscillatable about a first axis and a second axis that are perpendicular to each other, and the oscillation of the mirror portion about each axis causes laser light reflected by the mirror portion to be two-dimensionally scanned. In addition, a micromirror device that can perform Lissajous scanning of laser light by causing a mirror portion to resonate about each axis has been known.

In an image drawing apparatus using such a mirror device, in order to obtain a laser-drawn image having high image quality, it is necessary to estimate a scanning trajectory of laser light on a surface to be scanned and emit the laser light based on the estimated scanning trajectory.

JP2013-065923A discloses that, in a projector that projects an image onto a projection region by performing scanning with laser light, a scanning trajectory of the laser light is estimated based on image correction information including projection condition information.

WO2012/011183A discloses that in an image generation device that displays an image by scanning with laser light in a main scanning direction and a sub scanning direction by sinusoidal driving, a scanning trajectory is estimated based on a phase difference and a frequency ratio between the main scanning direction and the sub scanning direction.

### SUMMARY

In a mirror device in which a mirror portion is formed to be oscillatable about a first axis and a second axis perpendicular to each other, a so-called crosstalk occurs in which an angular variation of the mirror portion about one axis of the first axis and the second axis affects an angular variation of the mirror portion about the other axis.

JP2013-065923A and WO2012/011183A disclose estimation of a scanning trajectory, but neither of them takes crosstalk between the two axes into account, and thus it is difficult to accurately estimate the scanning trajectory. Therefore, in the techniques disclosed in JP2013-065923A and WO2012/011183A, a laser-drawn image having high image quality cannot be obtained.

An object of the technology of the present disclosure is to provide an image drawing apparatus and a driving method for the image drawing apparatus that enable obtaining a laser-drawn image having high image quality.

In order to achieve the above object, an image drawing apparatus including a light source that emits a light beam, a mirror device including a mirror portion having a reflecting surface that reflects the light beam, a first actuator that causes the mirror portion to oscillate about a first axis, and a second actuator that causes the mirror portion to oscillate about a second axis perpendicular to the first axis and a processor that controls operations of the light source and the mirror device to scan a surface to be scanned with the light beam reflected by the reflecting surface, in which, in a case where a deflection angle of the mirror portion about the first axis is denoted by a first deflection angle and a deflection angle of the mirror portion about the second axis is denoted by a second deflection angle, the processor estimates a scanning trajectory of the light beam on the surface to be scanned by using a first deflection angle estimation function that is a function of time for the first deflection angle and that takes into account that a temporal variation of the first deflection angle depends on the second deflection angle, and a second deflection angle estimation function that is a function of time for the second deflection angle and that takes into account that a temporal variation of the second deflection angle depends on the first deflection angle, and causes the light source to emit the light beam in correspondence with the estimated scanning trajectory and image information.

It is preferable that, in a case where a maximum amplitude of the first deflection angle is denoted by A₁, a maximum amplitude of the second deflection angle is denoted by A₂, an oscillation frequency of the mirror portion about the first axis is denoted by f₁, an oscillation frequency of the mirror portion about the second axis is denoted by f₂, a time is denoted by t, a constant is denoted by t₀, the first deflection angle at the time t is denoted by θ₁(t), and the second deflection angle at the time t is denoted by θ₂(t), the first deflection angle estimation function and the second deflection angle estimation function are represented by Equation (1) and Equation (2), respectively.

$${θ}_{1} ( t ) = {A}_{1} sin ( 2 π {f}_{1} ( t + {t}_{0} sin ( 2 π {f}_{2} t ) ) ) \qquad ( 1 )$$

$${θ}_{2} ( t ) = {A}_{2} sin ( 2 π {f}_{2} ( t + {t}_{0} sin ( 2 π {f}_{1} t ) ) ) \qquad ( 2 )$$

It is preferable that the light beam is incident perpendicularly to the reflecting surface in a case where the mirror portion is in a stationary state.

It is preferable that the processor estimates the scanning trajectory represented by coordinates x(t) and y(t) by inputting θ₁(t)derived by using Equation (1) and θ₂(t) derived by using Equation (2) to a coordinate conversion function represented by Equation (3).

$$( \begin{matrix}x ( t ) \\ y ( t )\end{matrix} ) = ( \begin{matrix}\frac{2 cos {θ}_{1} ( t ) cos {θ}_{2} ( t ) sin {θ}_{1} ( t )}{2 {cos}^{2} {θ}_{1} ( t ) {cos}^{2} {θ}_{2} ( t ) - 1} \\ \frac{- 2 cos {θ}_{1} ( t ) {cos}^{2} {θ}_{1} ( t ) sin {θ}_{2} ( t )}{2 {cos}^{2} {θ}_{1} ( t ) {cos}^{2} {θ}_{2} ( t ) - 1}\end{matrix} ) \qquad ( 3 )$$

It is preferable that the processor causes the mirror portion to resonate about each of the first axis and the second axis.

A driving method for an image drawing apparatus according to the present disclosure is a driving method for an image drawing apparatus including a light source that emits a light beam, a mirror device including a mirror portion having a reflecting surface that reflects the light beam, a first actuator that causes the mirror portion to oscillate about a first axis, and a second actuator that causes the mirror portion to oscillate about a second axis perpendicular to the first axis, and a processor that controls operations of the light source and the mirror device to scan a surface to be scanned with the light beam reflected by the reflecting surface, the driving method including in a case where a deflection angle of the mirror portion about the first axis is denoted by a first deflection angle and a deflection angle of the mirror portion about the second axis is denoted by a second deflection angle, estimating a scanning trajectory of the light beam on the surface to be scanned by using a first deflection angle estimation function that is a function of time for the first deflection angle and that takes into account that a temporal variation of the first deflection angle depends on the second deflection angle, and a second deflection angle estimation function that is a function of time for the second deflection angle and that takes into account that a temporal variation of the second deflection angle depends on the first deflection angle; and causing the light source to emit the light beam in correspondence with the estimated scanning trajectory and image information.

According to the technology of the present disclosure, it is possible to provide an image drawing apparatus and a driving method for the image drawing apparatus, which enable obtaining a laser-drawn image having high image quality.

### BRIEF DESCRIPTION OF THE DRAWINGS

Exemplary embodiments according to the technique of the present disclosure will be described in detail based on the following figures, wherein:

FIG. 1 is a diagram schematically showing an image drawing apparatus,

FIG. 2 is a diagram showing a configuration example including an optical system of the image drawing apparatus,

FIG. 3 is an external perspective view of a micromirror device,

FIG. 4 is a plan view of the micromirror device as viewed from a light incident side,

FIG. 5 is a cross-sectional view taken along the line A-A of FIG. 4,

FIG. 6 is a cross-sectional view taken along the line B-B of FIG. 4,

FIG. 7 is a cross-sectional view taken along the line C-C of FIG. 4,

FIG. 8 is a diagram showing an example in which a first actuator is driven,

FIG. 9 is a diagram showing an example in which a second actuator is driven,

FIGS. 10A and 10B are graphs showing examples of a first drive signal and a second drive signal,

FIG. 11 is a block diagram showing an example of a configuration of a control device,

FIG. 12 is a diagram showing an example of a flow of processing by a drawing control unit,

FIG. 13 is a diagram illustrating a scanning trajectory,

FIG. 14 is a diagram schematically illustrating a derivation method for a coordinate conversion function,

FIG. 15 is a diagram showing a configuration of an experimental image drawing apparatus,

FIG. 16 is a diagram showing a drawn image in a case where there is no crosstalk, and

FIG. 17 is a diagram showing a drawn image drawn by the experimental image drawing apparatus.

### DETAILED DESCRIPTION

An example of an embodiment according to the technology of the present disclosure will be described with reference to the accompanying drawings.

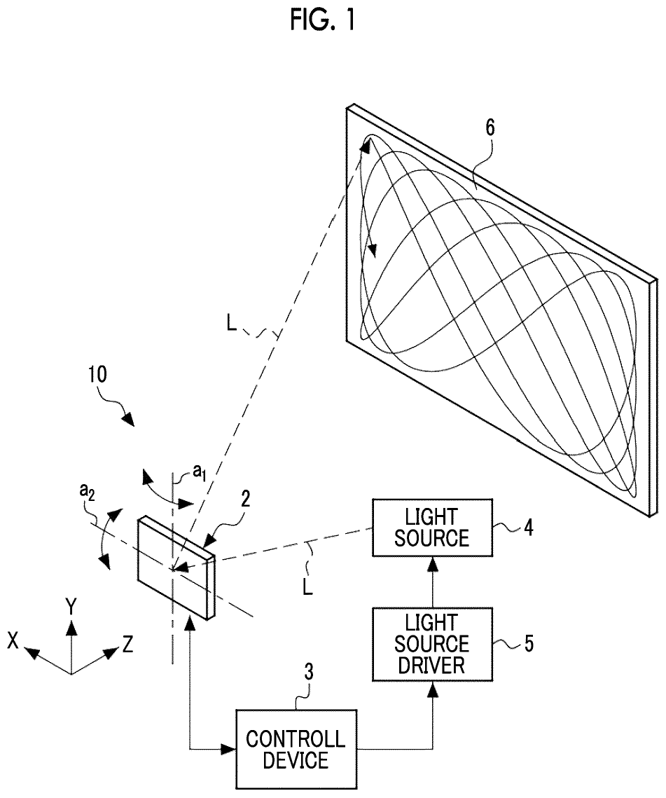

FIG. 1 is a diagram schematically showing an image drawing apparatus 10 according to an embodiment. The image drawing apparatus 10 comprises a micromirror device (hereinafter, referred to as MMD) 2, a control device 3, a light source 4, and a light source driver 5. The control device 3 is an example of a “processor” according to the technology of the present disclosure. The MMD 2 is an example of a “mirror device” according to the technology of the present disclosure.

The image drawing apparatus 10 draws an image on a surface to be scanned by reflecting a light beam L emitted from the light source 4 by the MMD 2 and optically scanning the surface to be scanned 6 with the reflected light beam under the control of the control device 3. The surface to be scanned 6 is, for example, a surface of a screen.

The image drawing apparatus 10 is applied to, for example, a Lissajous scanning type laser display. Specifically, the image drawing apparatus 10 can be applied to a laser scanning display such as augmented reality (AR) glass, virtual reality (VR) glass, and the like.

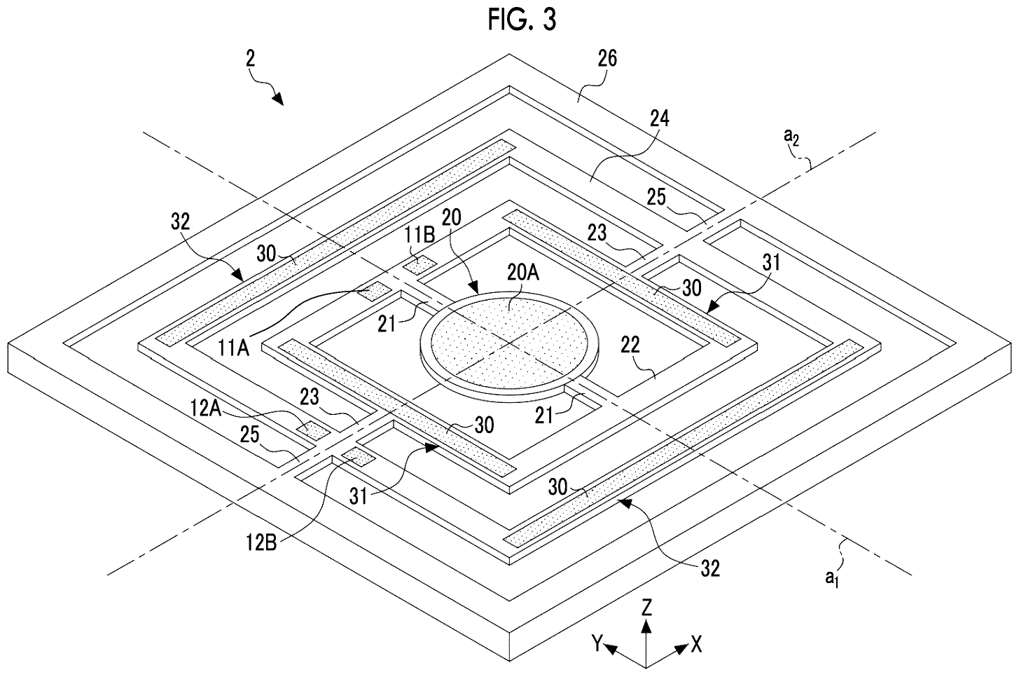

The MMD 2 is a piezoelectric biaxial drive-type mirror device capable of causing a mirror portion 20 (see FIG. 3) to oscillate about a first axis a₁ and a second axis a₂ perpendicular to the first axis a₁. Hereinafter, a direction parallel to the first axis a₁ is referred to as a Y direction, a direction parallel to the second axis a₂ is an X direction, and a direction perpendicular to the first axis a₁ and the second axis a₂ is referred to as a Z direction. In the present disclosure, the perpendicularity is not limited to a case where an angle at which the first axis a₁ and the second axis a₂ intersect each other is exactly 90°, and also includes a case where the angle is within a range including a manufacturing error with 90° as a reference.

The light source 4 is a laser device that emits, for example, laser light as the light beam L. The light beam L emitted from the light source 4 travels in a direction parallel to the Z direction through an optical system described below and is perpendicularly incident on the reflecting surface 20A (see FIG. 3) in a state where the mirror portion 20 of the MMD 2 is stationary.

The light source driver 5 is a drive circuit that supplies a drive current to the light source 4 under the control of the control device 3.

The control device 3 controls the operations of the MMD 2 and the light source 4 based on image information indicating an image to be drawn on the surface to be scanned 6. The light source driver 5 supplies a drive current to the light source 4 based on a control signal input from the control device 3 to cause the light source 4 to generate the light beam L. The MMD 2 causes the mirror portion 20 to oscillate about the first axis a₁ and the second axis a₂ based on a control signal input from the control device 3.

As will be described in detail below, the control device 3 causes the mirror portion 20 to resonate about the first axis a₁ and the second axis a₂, so that the surface to be scanned 6 is scanned with the light beam L reflected by the mirror portion 20 such that a Lissajous waveform is drawn. This optical scanning method is called a Lissajous scanning method.

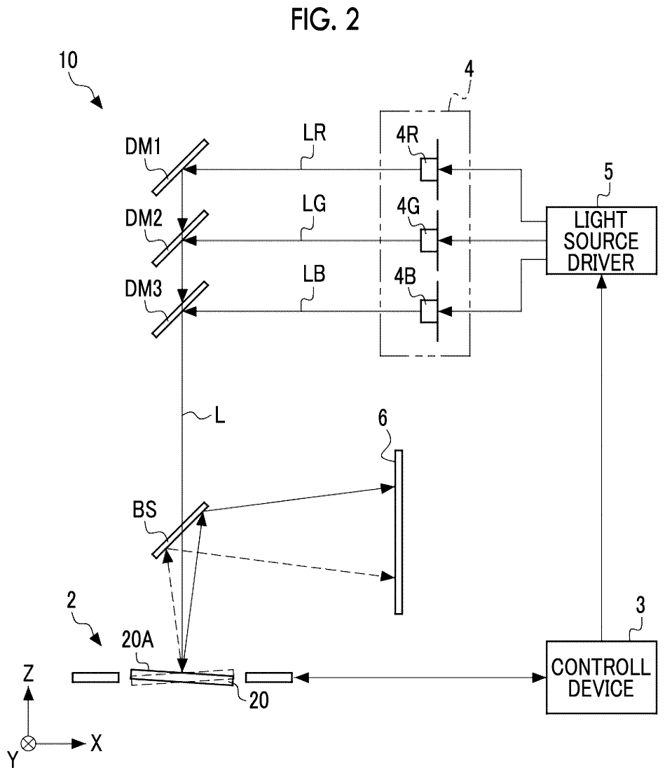

FIG. 2 shows a configuration example including an optical system of the image drawing apparatus 10. For example, the light source 4 is composed of a red laser diode 4R that generates red laser light LR, a green laser diode 4G that generates green laser light LG, and a blue laser diode 4B that generates blue laser light LB. In the present embodiment, the light beam L includes red laser light LR, green laser light LG, and blue laser light LB. Hereinafter, in a case where it is not necessary to distinguish between the red laser light LR, the green laser light LG, and the blue laser light LB, the light beams are simply referred to as a light beam L.

In order to integrate the optical paths of the red laser light LR, the green laser light LG, and the blue laser light LB emitted from the light source 4, first to third dichroic mirrors DM1 to DM3 are provided as an optical system. The first to third dichroic mirrors DM1 to DM3 integrate the optical paths of the red laser light LR, the green laser light LG, and the blue laser light LB, and cause the light beam L to travel in a direction parallel to the Z direction. Hereinafter, an optical path integrated by the first to third dichroic mirrors DM1 to DM3 will be referred to as an integrated optical path.

A beam splitter BS and the MMD 2 are disposed on the integrated optical path. For example, the beam splitter BS is configured with a half mirror. A part of the light beam L that travels along the integrated optical path and is incident on the beam splitter BS transmits through the beam splitter BS and is incident perpendicularly to the reflecting surface 20A in a case where the mirror portion 20 is in a stationary state. The light beam L is reflected by the reflecting surface 20A in a direction corresponding to an angle of the mirror portion 20 and is incident into the beam splitter BS. A part of the light beam L incident on the beam splitter BS from the MMD 2 is reflected by the beam splitter BS and is incident on the surface to be scanned 6.

In a case where each pixel of the image indicated by the image information includes color information, the control device 3 controls the light source driver 5 to cause a laser diode corresponding to the color information among the red laser diode 4R, the green laser diode 4G, and the blue laser diode 4B to emit light for each pixel.

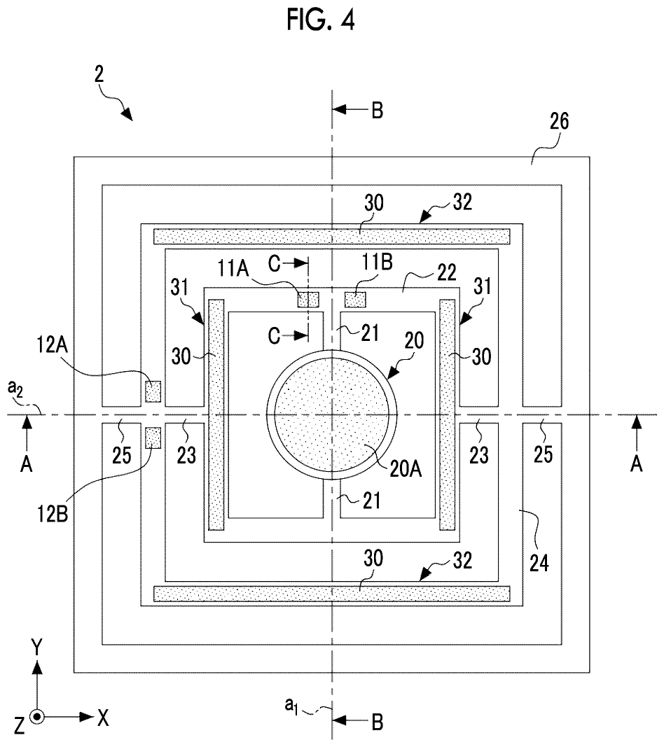

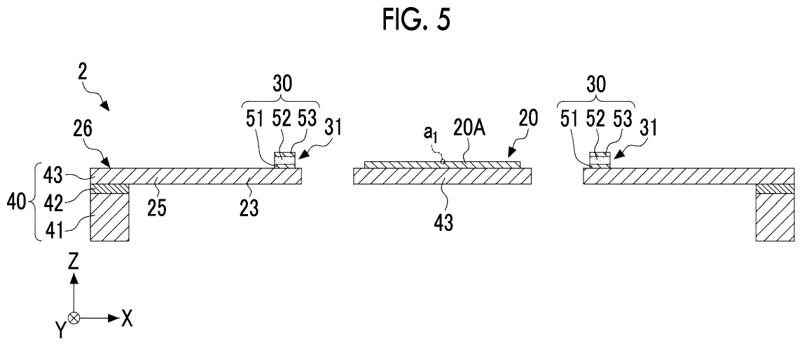

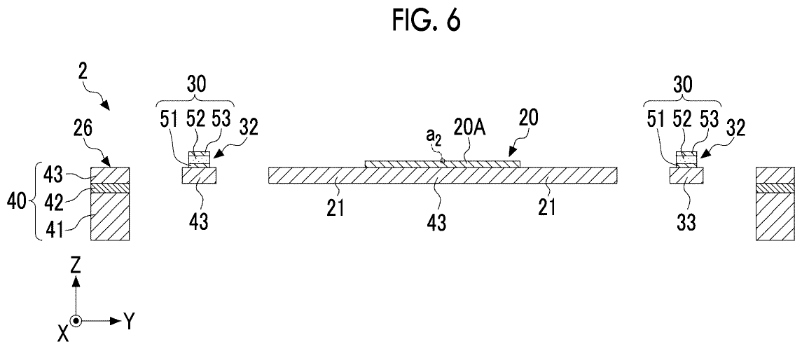

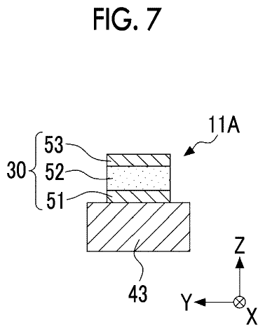

Next, an example of the MMD 2 will be described with reference to FIGS. 3 to 7. FIG. 3 is an external perspective view of the MMD 2. FIG. 4 is a plan view of the MMD 2 as viewed from a light incident side. FIG. 5 is a cross-sectional view taken along the line A-A in FIG. 4. FIG. 6 is a cross-sectional view taken along the line B-B in FIG. 4. FIG. 7 is a cross-sectional view taken along the line C-C of FIG. 4.

As shown in FIGS. 3 and 4, the MMD 2 includes a mirror portion 20, a first support portion 21, a first movable frame 22, a second support portion 23, a second movable frame 24, a connecting portion 25, and a fixed frame 26. The MMD 2 is a so-called MEMS scanner.

The mirror portion 20 has a reflecting surface 20A for reflecting incident light. The reflecting surface 20A is provided on one surface of the mirror portion 20 and formed of a metal thin film such as gold (Au), aluminum (Al), silver (Ag), or an alloy of silver. The shape of the reflecting surface 20A is, for example, circular with the intersection of the first axis a₁ and the second axis a₂ as the center.

The first axis a₁ and the second axis a₂ exist in a plane including the reflecting surface 20A in a case where the mirror portion 20 is stationary. The planar shape of the MMD 2 is rectangular, line-symmetrical with respect to the first axis a₁, and line-symmetrical with respect to the second axis a₂.

The first support portions 21 are disposed on an outside of the mirror portion 20 at positions facing each other across the second axis a₂. The first support portions 21 are connected to the mirror portion 20 on the first axis a₁, and oscillatably support the mirror portion 20 about the first axis a₁. In the present embodiment, the first support portions 21 are torsion bars that stretch along the first axis a₁.

The first movable frame 22 is a rectangular frame that surrounds the mirror portion 20 and is connected to the mirror portion 20 on the first axis a₁ via the first support portion 21. A piezoelectric element 30 is formed on the first movable frame 22 at each of positions that face each other with the first axis a₁ interposed therebetween. In this way, a pair of first actuators 31 are configured by forming two piezoelectric elements 30 on the first movable frame 22.

The pair of first actuators 31 are arranged at positions that face each other with the first axis a₁ interposed therebetween. The first actuators 31 cause the mirror portion 20 to oscillate about the first axis a₁ by applying rotational torque about the first axis a₁ to the mirror portion 20.

The second support portions 23 are disposed on an outside of the first movable frame 22 at positions facing each other across the first axis a₁. The second support portions 23 are connected to the first movable frame 22 on the second axis a₂ and support the first movable frame 22 and the mirror portion 20 to be oscillatable about the second axis a₂. In the present embodiment, the second support portion 23 is a torsion bar stretched along the second axis a₂.

The second movable frame 24 is a frame having a rectangular shape surrounding the first movable frame 22 and is connected to the first movable frame 22 through the second support portion 23 on the second axis a₂. The piezoelectric elements 30 are formed on the second movable frame 24 at positions facing each other across the second axis a₂. In this way, a pair of second actuators 32 are configured by forming two piezoelectric elements 30 on the second movable frame 24.

The pair of second actuators 32 are disposed at positions facing each other across the second axis a₂. The second actuators 32 cause the mirror portion 20 to oscillate about the second axis a₂ by applying rotational torque about the second axis a₂ to the mirror portion 20 and to the first movable frame 22.

The connecting portion 25 is arranged outside the second movable frame 24 at each of positions that face each other with the first axis a₁ interposed therebetween. The connecting portions 25 are connected to the second movable frame 24 on the second axis a₂.

The fixed frame 26 is a frame having a rectangular shape surrounding the second movable frame 24 and is connected to the second movable frame 24 through the connecting portion 25 on the second axis a₂.

The first movable frame 22 is provided with a pair of first angle detection sensors 11A and 11B at positions facing each other across the first axis a₁ in the vicinity of the first support portion 21. Each of the pair of first angle detection sensors 11A and 11B is configured with a piezoelectric element. Each of the first angle detection sensors 11A and 11B converts a force applied by deformation of the first support portion 21 with rotational movement of the mirror portion 20 about the first axis a₁ into a voltage and outputs a signal. That is, the first angle detection sensors 11A and 11B output signals corresponding to angles of the mirror portion 20 about the first axis a₁.

The second movable frame 24 is provided with a pair of second angle detection sensors 12A and 12B at positions facing each other across the second axis a₂ in the vicinity of the second support portion 23. Each of the pair of second angle detection sensors 12A and 12B is configured with a piezoelectric element. Each of the second angle detection sensors 12A and 12B converts a force applied by deformation of the second support portion 23 with rotational movement of the mirror portion 20 about the second axis a₂ into a voltage and outputs a signal. That is, the second angle detection sensors 12A and 12B output signals corresponding to angles of the mirror portion 20 about the second axis a₂.

In FIGS. 3 and 4, the wiring line and the electrode pad for giving the drive signal to the first actuator 31 and the second actuator 32 are not shown. In FIGS. 3 and 4, a wiring line and an electrode pad for outputting signals from the first angle detection sensors 11A and 11B and the second angle detection sensors 12A and 12B are not shown. A plurality of the electrode pads are provided on the fixed frame 26.

As shown in FIGS. 5 and 6, the MMD 2 is formed, for example, by performing an etching treatment on a silicon on insulator (SOI) substrate 40. The SOI substrate 40 is a substrate in which a silicon oxide layer 42 is provided on a first silicon active layer 41 made of single crystal silicon, and a second silicon active layer 43 made of single crystal silicon is provided on the silicon oxide layer 42.

The mirror portion 20, the first support portion 21, the first movable frame 22, the second support portion 23, the second movable frame 24, and the connecting portion 25 are formed of the second silicon active layer 43 remaining by removing the first silicon active layer 41 and the silicon oxide layer 42 from the SOI substrate 40 by an etching treatment. The second silicon active layer 43 functions as an elastic portion having elasticity. The fixed frame 26 is formed of three layers of the first silicon active layer 41, the silicon oxide layer 42, and the second silicon active layer 43.

The first actuator 31 and the second actuator 32 have the piezoelectric element 30 on the second silicon active layer 43. The piezoelectric element 30 has a laminated structure in which a lower electrode 51, a piezoelectric film 52, and an upper electrode 53 are sequentially laminated on the second silicon active layer 43. An insulating film is provided on the upper electrode 53, but is not shown.

The upper electrode 53 and the lower electrode 51 are formed of, for example, gold (Au) or platinum (Pt). The piezoelectric film 52 is formed of, for example, lead zirconate titanate (PZT), which is a piezoelectric material. The upper electrode 53 and the lower electrode 51 are electrically connected to the control device 3 described above via the wiring line and the electrode pad.

A drive voltage is applied to the upper electrode 53 from the control device 3. The lower electrode 51 is connected to the control device 3 via a wiring line and an electrode pad, and a reference potential (for example, a ground potential) is applied to the lower electrode 51.

In a case in which a positive or negative voltage is applied to the piezoelectric film 52 in the polarization direction, deformation (for example, expansion and contraction) proportional to the applied voltage occurs. That is, the piezoelectric film 52 exerts a so-called inverse piezoelectric effect. The piezoelectric film 52 exerts an inverse piezoelectric effect by applying a drive voltage from the control device 3 to the upper electrode 53, and displaces the first actuator 31 and the second actuator 32.

As shown in FIG. 7, the first angle detection sensor 11A is also similarly configured with the piezoelectric element 30 consisting of the lower electrode 51, the piezoelectric film 52, and the upper electrode 53 laminated on the second silicon active layer 43. In a case where force (pressure) is applied to the piezoelectric film 52, polarization proportional to the pressure is generated. That is, the piezoelectric film 52 exerts a piezoelectric effect. The piezoelectric film 52 exerts a piezoelectric effect and generates a voltage in a case where a force is applied by deformation of the first support portion 21 with rotational movement of the mirror portion 20 about the first axis a₁.

Since the first angle detection sensor 11B has the same configuration as the first angle detection sensor 11A, the first angle detection sensor 11B is not shown. In addition, since the second angle detection sensors 12A and 12B have the same configuration as the first angle detection sensor 11A, the second angle detection sensors 12A and 12B are not shown.

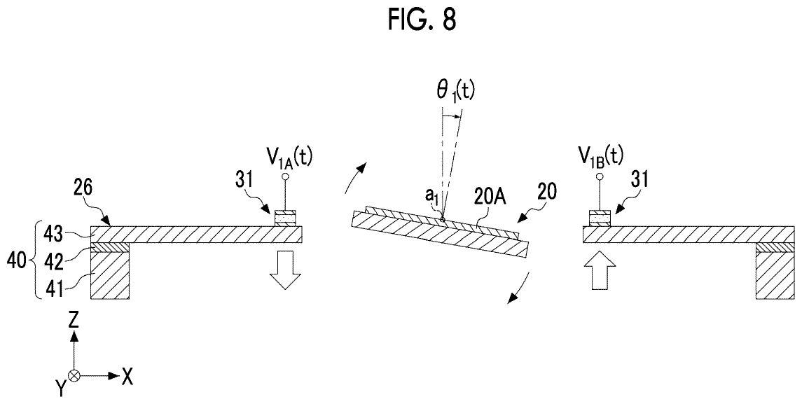

FIG. 8 shows an example in which one piezoelectric film 52 of the pair of first actuators 31 is extended and the other piezoelectric film 52 is contracted, thereby generating rotational torque about the first axis a₁ in the first actuator 31. In this way, one of the pair of first actuators 31 and the other are displaced in opposite directions to each other, whereby the mirror portion 20 moves rotationally about the first axis a₁.

In addition, FIG. 8 shows an example in which the first actuator 31 is driven in an anti-phase resonance mode in which the displacement direction of the pair of first actuators 31 and a rotational movement direction of the mirror portion 20 are opposite to each other. The first actuator 31 may be driven in an in-phase resonance mode in which the displacement direction of the pair of first actuators 31 and the rotational movement direction of the mirror portion 20 are the same direction.

A deflection angle (hereinafter, referred to as a first deflection angle) θ₁(t) of the mirror portion 20 about the first axis a₁ is controlled by the drive signal (hereinafter, referred to as a first drive signal) given to the first actuator 31 by the control device 3. The first drive signal is, for example, a sinusoidal AC voltage. The first drive signal includes a drive voltage waveform V_{1A}(t) applied to one of the pair of first actuators 31 and a drive voltage waveform V_{1B}(t) applied to the other. The drive voltage waveform V_{1A}(t) and the drive voltage waveform V_{1B}(t) are in an anti-phase with each other (that is, the phase difference is 180°).

The first deflection angle θ₁(t) is an angle at which a line normal to the reflecting surface 20A is inclined with respect to the Z direction in an XZ plane.

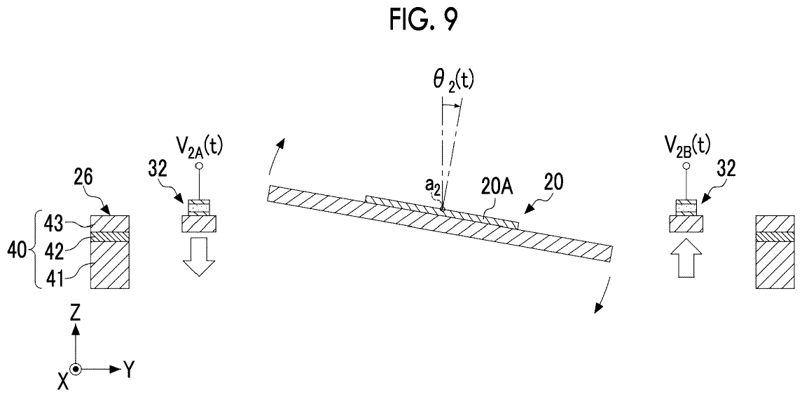

FIG. 9 shows an example in which one piezoelectric film 52 of the pair of second actuators 32 is extended and the other piezoelectric film 52 is contracted, thereby generating rotational torque about the second axis a₂ in the second actuator 32. In this way, one of the pair of second actuators 32 and the other are displaced in opposite directions to each other, whereby the mirror portion 20 moves rotationally about the second axis a₂.

In addition, FIG. 9 shows an example in which the second actuator 32 is driven in an anti-phase resonance mode in which the displacement direction of the pair of second actuators 32 and the rotational movement direction of the mirror portion 20 are opposite to each other. The second actuator 32 may be driven in an in-phase resonance mode in which the displacement direction of the pair of second actuators 32 and the rotational movement direction of the mirror portion 20 are the same direction.

A deflection angle (hereinafter, referred to as a second deflection angle) θ₂(t) of the mirror portion 20 about the second axis a₂ is controlled by the drive signal (hereinafter, referred to as a second drive signal) given to the second actuator 32 by the control device 3. The second drive signal is, for example, a sinusoidal AC voltage. The second drive signal includes a drive voltage waveform V_{2A}(t) applied to one of the pair of second actuators 32 and a drive voltage waveform V_{2B}(t) applied to the other. The drive voltage waveform V_{2A}(t) and the drive voltage waveform V_{2B}(t) are in an anti-phase with each other (that is, the phase difference is 180°.

The second deflection angle θ₂(t) is an angle at which the line normal to the reflecting surface 20A is inclined with respect to the Z direction in a YZ plane.

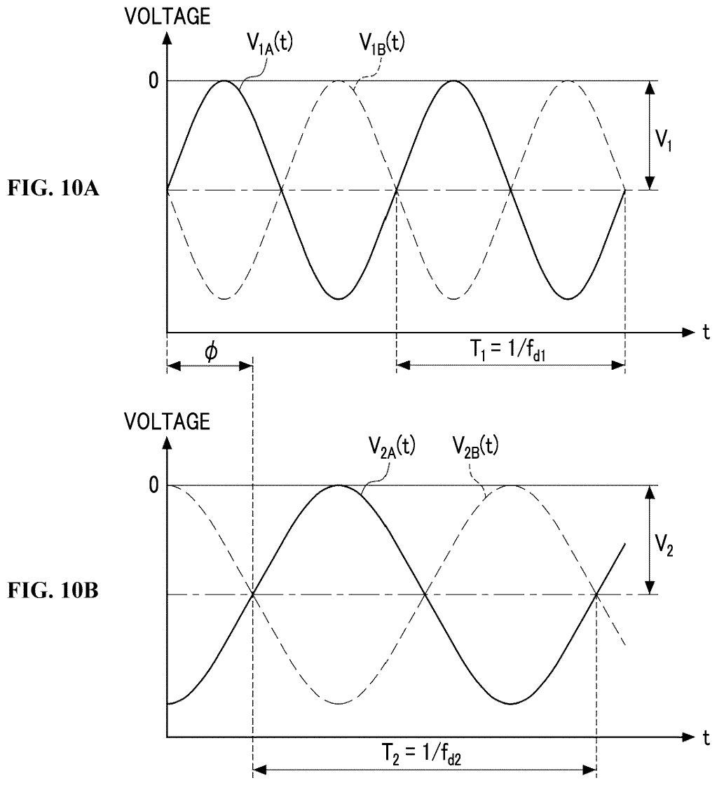

FIGS. 10A and 10B show examples of the first drive signal and the second drive signal. FIG. 10A shows the drive voltage waveforms V_{1A}(t) and V_{1B}(t) included in the first drive signal. FIG. 10B shows the drive voltage waveforms V_{2A}(t) and V_{2B}(t) included in the second drive signal.

The drive voltage waveforms V_{1A}(t) and V_{1B}(t) are represented as follows, respectively.

$$\begin{matrix}{V}_{1 A} ( t ) = {V}_{1} sin ( 2 π {f}_{d 1} t ) - {V}_{1} \\ {V}_{1 B} ( t ) = {V}_{1} sin ( 2 π {f}_{d 1} t + α ) - {V}_{1}\end{matrix}$$

Here, V₁ is an amplitude voltage. f_{d1} is the drive frequency (hereinafter, referred to as the first drive frequency). t is time. α is the phase difference between the drive voltage waveforms V_{1A}(t) and V_{1B}(t). In the present embodiment, for example, α=180°.

By applying the drive voltage waveforms V_{1A}(t) and V_{1B}(t) to the pair of first actuators 31, the mirror portion 20 oscillates about the first axis a₁ at the first drive frequency f_{d1} (see FIG. 8).

The drive voltage waveforms V_{2A}(t) and V_{2B}(t) are represented as follows, respectively.

$$\begin{matrix}{V}_{2 A} ( t ) = {V}_{2} sin ( 2 π {f}_{d 2} t + φ ) - {V}_{2} \\ {V}_{2 B} ( t ) = {V}_{2} sin ( 2 π {f}_{d 2} t + β + φ ) - {V}_{2}\end{matrix}$$

Here, V₂ is an amplitude voltage. f_{d2} is the drive frequency (hereinafter, referred to as the second drive frequency). t is time. β is a phase difference between the drive voltage waveforms V_{2A}(t) and V_{2B}(t). In the present embodiment, for example, β=180°. In addition, φ is the phase difference between the drive voltage waveforms V_{1A}(t) and V_{1B}(t) and the drive voltage waveforms V_{2A}(t) and V_{2B}(t).

By applying the drive voltage waveforms V_{2A}(t) and V_{2B}(t) to the pair of second actuators 32, the mirror portion 20 oscillates about the second axis a₂ at the second drive frequency f_{d2} (see FIG. 9).

The first drive frequency f_{d1} is set to match a resonance frequency of the mirror portion 20 about the first axis a₁. The second drive frequency f_{d2} is set to match the resonance frequency about the second axis a₂ of the mirror portion 20.

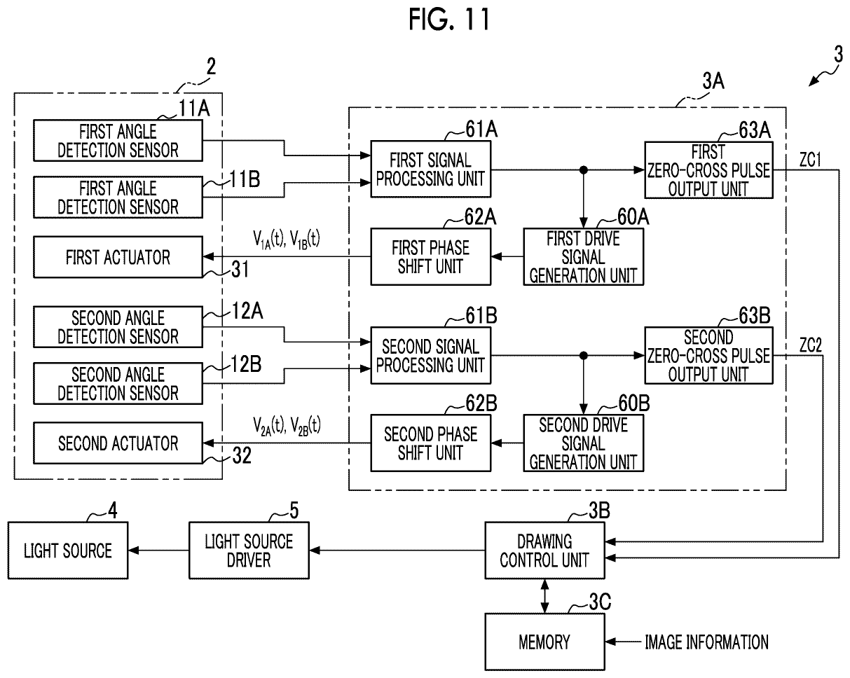

FIG. 11 shows an example of a configuration of the control device 3. The control device 3 includes a mirror control unit 3A and a drawing control unit 3B. The mirror control unit 3A includes a first drive signal generation unit 60A, a first signal processing unit 61A, a first phase shift unit 62A, a first zero-cross pulse output unit 63A, a second drive signal generation unit 60B, a second signal processing unit 61B, a second phase shift unit 62B, and a second zero-cross pulse output unit 63B.

The first drive signal generation unit 60A, the first signal processing unit 61A, and the first phase shift unit 62A perform feedback control such that the oscillation of the mirror portion 20 about the first axis a₁ maintains a resonance state. The second drive signal generation unit 60B, the second signal processing unit 61B, and the second phase shift unit 62B perform feedback control such that the oscillation of the mirror portion 20 about the second axis a₂ maintains a resonance state.

The first drive signal generation unit 60A generates the first drive signal including the above-described drive voltage waveforms V_{1A}(t) and V_{1B}(t) based on a reference waveform, and applies the generated first drive signal to the pair of first actuators 31 via the first phase shift unit 62A. Accordingly, the mirror portion 20 oscillates about the first axis a₁. The first angle detection sensors 11A and 11B output signals corresponding to angles of the mirror portion 20 about the first axis a₁. The signals output from the first angle detection sensors 11A and 11B are waveform signals similar to a sinusoidal wave having the first drive frequency f_{d1} and are in anti-phase with each other.

The second drive signal generation unit 60B generates the second drive signal including the drive voltage waveforms V_{2A}(t) and V_{2B}(t) based on the reference waveform and provides the generated second drive signal to the pair of second actuators 32 through the second phase shift unit 62B. Accordingly, the mirror portion 20 oscillates about the second axis a₂. The second angle detection sensors 12A and 12B output signals corresponding to angles of the mirror portion 20 about the second axis a₂. The signals output from the second angle detection sensors 12A and 12B are waveform signals similar to a sinusoidal wave having the second drive frequency f_{d2} and are in anti-phase with each other.

The first drive signal generated by the first drive signal generation unit 60A and the second drive signal generated by the second drive signal generation unit 60B are phase-synchronized.

The first signal processing unit 61A generates a signal from which the vibration noise has been removed (hereinafter, a first angle detection signal) based on the signals output from the pair of first angle detection sensors 11A and 11B. For example, the first signal processing unit 61A generates the first angle detection signal by subtracting the signal output from the first angle detection sensor 11B from the signal output from the first angle detection sensor 11A.

The second signal processing unit 61B generates a signal from which the vibration noise has been removed (hereinafter, a second angle detection signal) based on the signals output from the pair of second angle detection sensors 12A and 12B. For example, the second signal processing unit 61B generates the second angle detection signal by subtracting the signal output from the second angle detection sensor 12B from the signal output from the second angle detection sensor 12A.

The first angle detection signal input from the first signal processing unit 61A is fed back to the first drive signal generation unit 60A. The first phase shift unit 62A shifts the phase of the drive voltage waveform output from the first drive signal generation unit 60A. For example, the first phase shift unit 62A shifts the phases by 90°.

The second angle detection signal input from the second signal processing unit 61B is fed back to the second drive signal generation unit 60B. The second phase shift unit 62B shifts the phase of the drive voltage waveform output from the second drive signal generation unit 60B. The second phase shift unit 62B shifts the phase by 90°, for example.

The first zero-cross pulse output unit 63A generates a zero-cross pulse (hereinafter, referred to as a first zero-cross pulse) ZC1 based on the first angle detection signal input from the first signal processing unit 61A. The first zero-cross pulse output unit 63A generates the first zero-cross pulse ZC1 at a timing at which the first angle detection signal, which is an AC signal, crosses zero volt. The first zero-cross pulse ZC1 is basically generated at a timing at which θ₁(t)=0. The first zero-cross pulse output unit 63A inputs the generated first zero-cross pulse ZC1 to the drawing control unit 3B.

The second zero-cross pulse output unit 63B generates a zero-cross pulse (hereinafter, referred to as a second zero-cross pulse) ZC2 based on the second angle detection signal input from the second signal processing unit 61B. The second zero-cross pulse output unit 63B generates the second zero-cross pulse ZC2 at a timing at which the second angle detection signal that is an alternating current signal crosses zero volts. The second zero-cross pulse ZC2 is basically generated at a timing at which θ₂(t)=0. The second zero-cross pulse output unit 63B inputs the generated second zero-cross pulse ZC2 to the drawing control unit 3B.

The drawing control unit 3B estimates a scanning trajectory of the light beam L on the surface to be scanned 6, and controls the light emission of the light source 4 in correspondence with the estimated scanning trajectory and the image information. The drawing control unit 3B is configured with a processor such as a central processing unit (CPU), and executes processing based on a program stored in Lout. The image information is stored in, for example, a memory 3C.

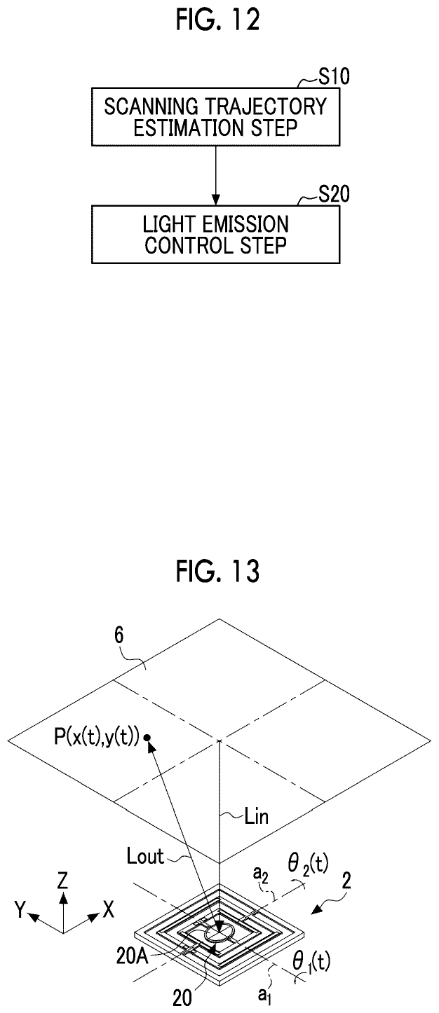

FIG. 12 shows an example of the flow of the process performed by the drawing control unit 3B. The drawing control unit 3B executes a scanning trajectory estimation step S10 of estimating the scanning trajectory and a light emission control step S20 of controlling the light emission of the light source 4.

In the scanning trajectory estimation step S10, first, the drawing control unit 3B estimates the first deflection angle θ₁(t) and the second deflection angle θ₂(t) based on a first deflection angle estimation function represented by Equation (1) and a second deflection angle estimation function represented by Equation (2).

$${θ}_{1} ( t ) = {A}_{1} sin ( 2 π {f}_{1} ( t + {t}_{0} sin ( 2 π {f}_{2} t ) ) ) \qquad ( 1 )$$

$${θ}_{2} ( t ) = {A}_{2} sin ( 2 π {f}_{2} ( t + {t}_{0} sin ( 2 π {f}_{1} t ) ) ) \qquad ( 2 )$$

Here, A₁ is the maximum amplitude of the first deflection angle θ₁(t), and A₂ is the maximum amplitude of the second deflection angle θ₂(t). t₀ is a constant derived from experiments or the like described later. In addition, f₁ is an oscillation frequency of the mirror portion 20 about the first axis a₁, and f₂ is an oscillation frequency of the mirror portion 20 about the second axis a₂. The oscillation frequency f₁ is equal to the first drive frequency f_{d1}. The oscillation frequency f₂ is equal to the second drive frequency f_{d2}. The first deflection angle estimation function and the second deflection angle estimation function represented by Equation (1) and Equation (2) are stored in, for example, the memory 3C.

The first deflection angle estimation function is a function of time for the first deflection angle θ₁(t), and which takes into account that the temporal variation of the first deflection angle θ₁(t) depends on the second deflection angle θ₂(t). The second deflection angle estimation function is a function of time for the second deflection angle θ₂(t), and which takes into account that the temporal variation of the second deflection angle θ₂(t) depends on the first deflection angle θ₁(t). That is, the first deflection angle estimation function and the second deflection angle estimation function are angle estimation functions in which the influence of so-called crosstalk is taken into account, the crosstalk being a phenomenon in which the angular variation of the mirror portion 20 about one axis of the first axis a₁ and the second axis a₂ affects the angular variation of the mirror portion 20 about the other axis.

Next, the drawing control unit 3B estimates the scanning trajectory by inputting the first deflection angle θ₁(t) derived by the first deflection angle estimation function and the second deflection angle θ₂(t) derived by the second deflection angle estimation function to a coordinate conversion function represented by Equation (3).

$$( \begin{matrix}x ( t ) \\ y ( t )\end{matrix} ) = ( \begin{matrix}\frac{2 cos {θ}_{1} ( t ) cos {θ}_{2} ( t ) sin {θ}_{1} ( t )}{2 {cos}^{2} {θ}_{1} ( t ) {cos}^{2} {θ}_{2} ( t ) - 1} \\ \frac{- 2 cos {θ}_{1} ( t ) {cos}^{2} {θ}_{1} ( t ) sin {θ}_{2} ( t )}{2 {cos}^{2} {θ}_{1} ( t ) {cos}^{2} {θ}_{2} ( t ) - 1}\end{matrix} ) \qquad ( 3 )$$

Here, x(t) and y(t) represent coordinates of a scanning trajectory on the surface to be scanned 6. The coordinate conversion function represented by Equation (3) is stored in, for example, the memory 3C.

As shown in FIG. 13, an incidence vector of a light beam L incident on the reflecting surface 20A of the mirror portion 20 is denoted by Lin, and the surface to be scanned 6 is a plane perpendicular to the incidence vector Lin and having a distance of 1 to the reflecting surface 20A. The coordinates of the scanning trajectory are represented as an X coordinate and a Y coordinate of an intersection P between the pointing vector Lout and the surface to be scanned 6.

In the light emission control step S20, the drawing control unit 3B controls the light source driver 5 in correspondence with the estimated scanning trajectory and the image information to control the light emission of the light source 4. In addition, the drawing control unit 3B controls the light emission timing such that the light emission timing of the light source 4 is synchronized with the first zero-cross pulse ZC1 and the second zero-cross pulse ZC2 input from the mirror control unit 3A.

As described above, in the present embodiment, the first deflection angle θ₁(t) and the second deflection angle θ₂(t) are estimated by using the first deflection angle estimation function and the second deflection angle estimation function in which the influence of the crosstalk is taken into account, and the estimated first deflection angle θ₁(t) and the estimated second deflection angle θ₂(t) are subjected to coordinate conversion to estimate the scanning trajectory. Therefore, it is possible to obtain a laser-drawn image having high image quality.

### Coordinate Conversion Function

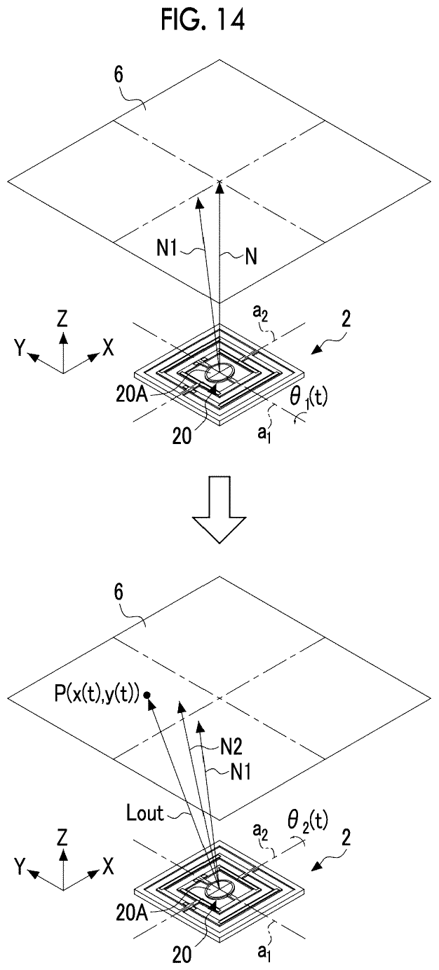

Next, the coordinate conversion function will be described. FIG. 14 schematically describes a derivation method for the coordinate conversion function. First, a normal vector of the reflecting surface 20A in a state where the mirror portion 20 is stationary state is denoted by N. Next, a normal vector after rotation in a case where the mirror portion 20 is rotated by the first deflection angle θ₁(t) about the first axis a₁ is denoted by N1, and the normal vector N1 is derived based on the normal vector N. Next, a normal vector after rotation in a case where the mirror portion 20 is rotated by the second deflection angle θ₂(t) about the second axis a₂ is denoted by N2, and the normal vector N2 is derived based on the normal vector N1. Then, the pointing vector Lout is derived based on the normal vector N2, and the coordinates of the intersection point P between the pointing vector Lout and the surface to be scanned 6 are derived. The coordinates of the intersection P are represented by Equation (3). Equation (3) is a coordinate conversion function that converts the first deflection angle θ₁(t) and the second deflection angle θ₂(t) at time t into coordinates on the surface to be scanned 6.

The coordinate conversion function substantially the same as Equation (3) is known by Xichen Wang, Yingke Xie, Hengheng Liang, and Nianbing Zhong, “Analysis of Distortion Based on 2D MEMS Micromirror Scanning Projection System”, Micromachines 2021, 12, 818. Retrieved from the Internet: <https://www.mdpi.com/2072-666X/12/7/818/pdf-vor>.

### First and Second Deflection Angle Estimation Functions

Next, the first and second deflection angle estimation functions will be described. In the MMD 2, crosstalk occurs in principle between the first deflection angle θ₁(t) and the second deflection angle θ₂(t). Therefore, it is considered to solve a motion equation representing the motion of the gimbal type biaxial mirror and to obtain the temporal variation of the first deflection angle θ₁(t) and the second deflection angle θ₂(t). However, in practice, it is difficult to analytically solve the motion equation represented by the differential equation and to obtain the temporal variation of the first deflection angle θ₁(t) and the second deflection angle θ₂(t). Therefore, the present applicant has found a method for experimentally obtaining the temporal variation of the first deflection angle θ₁(t) and the second deflection angle θ₂(t).

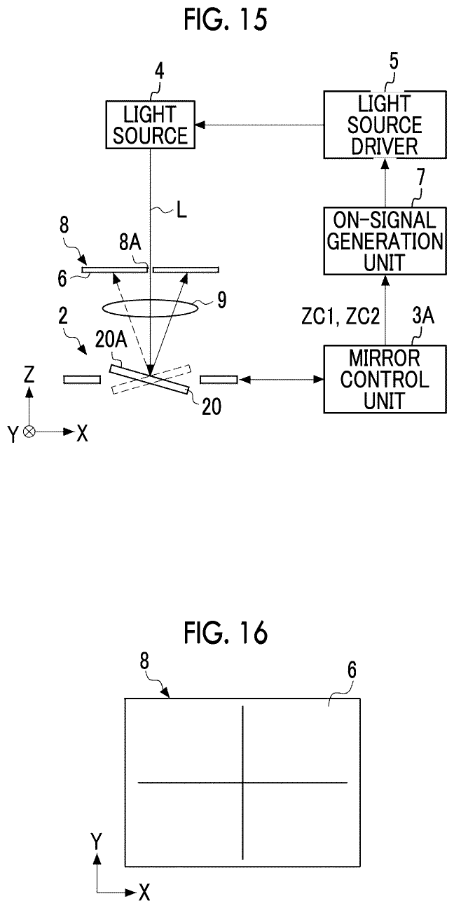

FIG. 15 shows a configuration of an experimental image drawing apparatus 10A. The experimental image drawing apparatus 10A is provided with an on-signal generation unit 7 instead of the drawing control unit 3B. The on-signal generation unit 7 is configured of, for example, a field programmable gate array (FPGA). The first zero-cross pulse ZC1 and the second zero-cross pulse ZC2 are input to the on-signal generation unit 7 from the mirror control unit 3A. The on-signal generation unit 7 inputs an ON signal to the light source driver 5 in a case where the first zero-cross pulse ZC1 or the second zero-cross pulse ZC2 is input. The light source driver 5 supplies a drive current to the light source 4 in response to the input ON signal to cause the light source 4 to generate laser light. In the experimental image drawing apparatus 10A, the light source 4 is, for example, one laser diode.

In the experimental image drawing apparatus 10A, a screen 8 is disposed to be perpendicular to the optical path of the light beam L emitted from the light source 4. In addition, a fθ lens 9 is disposed between the screen 8 and the mirror portion 20. The light beam L emitted from the light source 4 passes through the through-hole 8A provided at a center of the screen 8 and passes through a center of the fθ lens 9 to be incident on the reflecting surface 20A of the mirror portion 20. The light beam L reflected by the reflecting surface 20A is imaged on the surface to be scanned 6, which is the surface of the screen 8, via the fθ lens 9.

FIG. 16 shows a drawn image in a case where there is no crosstalk between the first deflection angle θ₁(t) and the second deflection angle θ₂(t). In a case where there is no crosstalk, the drawn image has a cross shape in which two straight lines intersect with each other at right angles.

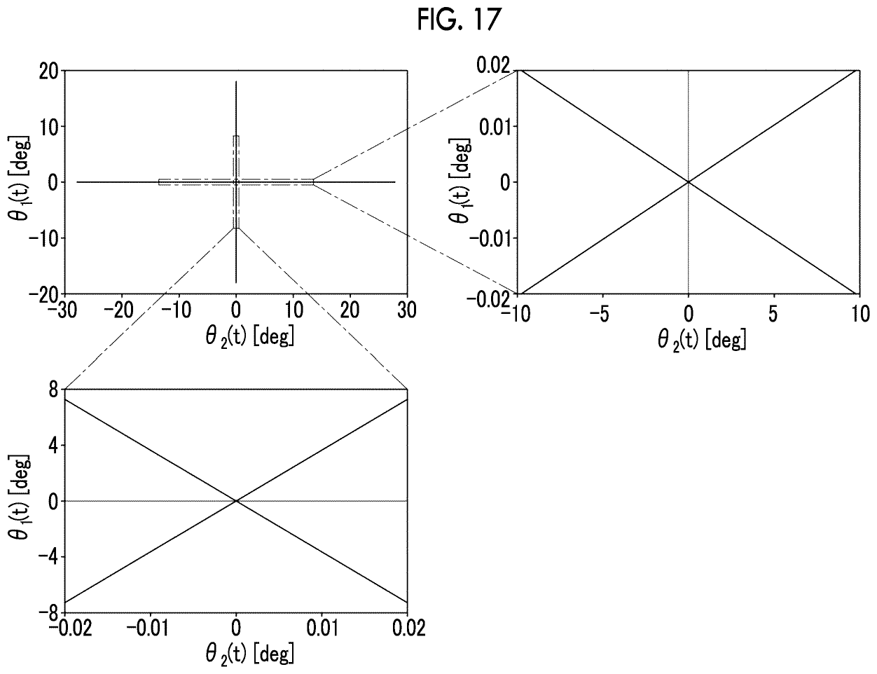

FIG. 17 shows a drawn image drawn by the experimental image drawing apparatus 10A. Since the image is formed by the fθ lens 9, the X coordinate and the Y coordinate on the surface to be scanned 6 are represented by the first deflection angle θ₁(t) and the second deflection angle θ₂(t). The present applicant has found that, in a case where the crosstalk occurs, the drawn image is not exactly cross-shaped, and the drawn image is slightly displaced from the cross shape as shown in the two enlarged views in FIG. 17. The present experimental results were also reproduced by calculation simulation.

The present applicant has found that the experimental results and the simulation results shown in FIG. 17 are reproduced by representing the first deflection angle θ₁(t) and the second deflection angle θ₂(t) by Equation (1) and Equation (2). A constant to in Equation (1) and Equation (2) is obtained by searching for an optimum value to reproduce the experimental result. As a result of performing the measurement in a certain MEMS device, a typical value of the constant t₀ was t₀=1×10⁻⁷. In a case where the crosstalk is large, the constant to tends to be large, and in a case where the crosstalk is small, the constant to tends to be small.

The configuration of the MMD 2 shown in the above embodiment is an example. The configuration of the MMD 2 can be variously modified. For example, the first actuator 31 that causes the mirror portion 20 to oscillate about the first axis a₁ may be disposed on the second movable frame 24, and the second actuator 32 that causes the mirror portion 20 to oscillate about the second axis a₂ may be disposed on the first movable frame 22.

In addition, various modifications can be made to a hardware configuration of the control device 3. The control device 3 may be configured with one processor or may be configured with a combination of two or more processors of the same type or different types. The processor includes, for example, a CPU, a programmable logic device (PLD), or a dedicated electric circuit. As is well known, the CPU is a general-purpose processor that executes software (program) to function as various processing units. The PLD is a processor such as a field programmable gate array (FPGA) whose circuit configuration can be changed after manufacture. The dedicated electric circuit is a processor that has a dedicated circuit configuration designed to perform a specific process, such as an application specific integrated circuit (ASIC).

All of the publications, the patent applications, and the technical standards described in the specification are incorporated by reference herein to the same extent as each individual document, each patent application, and each technical standard are specifically and individually stated to be incorporated by reference.

What is claimed is:

1. An image drawing apparatus comprising:
a light source that emits a light beam;
a mirror device including a mirror portion having a reflecting surface that reflects the light beam, a first actuator that causes the mirror portion to oscillate about a first axis, and a second actuator that causes the mirror portion to oscillate about a second axis perpendicular to the first axis; and
a processor that controls operations of the light source and the mirror device to scan a surface to be scanned with the light beam reflected by the reflecting surface,
wherein, in a case where a deflection angle of the mirror portion about the first axis is denoted by a first deflection angle and a deflection angle of the mirror portion about the second axis is denoted by a second deflection angle,
the processor
estimates a scanning trajectory of the light beam on the surface to be scanned by using a first deflection angle estimation function that is a function of time for the first deflection angle and that takes into account that a temporal variation of the first deflection angle depends on the second deflection angle, and a second deflection angle estimation function that is a function of time for the second deflection angle and that takes into account that a temporal variation of the second deflection angle depends on the first deflection angle, and
causes the light source to emit the light beam in correspondence with the estimated scanning trajectory and image information.

2. The image drawing apparatus according to claim 1,
wherein, in a case where a maximum amplitude of the first deflection angle is denoted by A₁, a maximum amplitude of the second deflection angle is denoted by A₂, an oscillation frequency of the mirror portion about the first axis is denoted by f₁, an oscillation frequency of the mirror portion about the second axis is denoted by f₂, a time is denoted by t, a constant is denoted by t₀, the first deflection angle at the time t is denoted by θ₁(t), and the second deflection angle at the time t is denoted by θ₂(t), the first deflection angle estimation function and the second deflection angle estimation function are represented by Equation (1) and Equation (2), respectively.
$${θ}_{1} ( t ) = {A}_{1} sin ( 2 π {f}_{1} ( t + {t}_{0} sin ( 2 π {f}_{2} t ) ) ) \qquad ( 1 )$$
$${θ}_{2} ( t ) = {A}_{2} sin ( 2 π {f}_{2} ( t + {t}_{0} sin ( 2 π {f}_{1} t ) ) ) \qquad ( 2 )$$

3. The image drawing apparatus according to claim 2,
wherein the light beam is incident perpendicularly to the reflecting surface in a case where the mirror portion is in a stationary state.

4. The image drawing apparatus according to claim 3,
wherein the processor estimates the scanning trajectory represented by coordinates x(t) and y(t) by inputting θ₁(t) derived by using Equation (1) and θ₂(t) derived by using Equation (2) to a coordinate conversion function represented by Equation (3).
$$( \begin{matrix}x ( t ) \\ y ( t )\end{matrix} ) = ( \begin{matrix}\frac{2 cos {θ}_{1} ( t ) cos {θ}_{2} ( t ) sin {θ}_{1} ( t )}{2 {cos}^{2} {θ}_{1} ( t ) {cos}^{2} {θ}_{2} ( t ) - 1} \\ \frac{- 2 cos {θ}_{1} ( t ) {cos}^{2} {θ}_{1} ( t ) sin {θ}_{2} ( t )}{2 {cos}^{2} {θ}_{1} ( t ) {cos}^{2} {θ}_{2} ( t ) - 1}\end{matrix} ) \qquad ( 3 )$$

5. The image drawing apparatus according to claim 4,
wherein the processor causes the mirror portion to resonate about each of the first axis and the second axis.

6. A driving method for an image drawing apparatus including a light source that emits a light beam, a mirror device including a mirror portion having a reflecting surface that reflects the light beam, a first actuator that causes the mirror portion to oscillate about a first axis, and a second actuator that causes the mirror portion to oscillate about a second axis perpendicular to the first axis, and a processor that controls operations of the light source and the mirror device to scan a surface to be scanned with the light beam reflected by the reflecting surface, the driving method comprising:
in a case where a deflection angle of the mirror portion about the first axis is denoted by a first deflection angle and a deflection angle of the mirror portion about the second axis is denoted by a second deflection angle,
estimating a scanning trajectory of the light beam on the surface to be scanned by using a first deflection angle estimation function that is a function of time for the first deflection angle and that takes into account that a temporal variation of the first deflection angle depends on the second deflection angle, and a second deflection angle estimation function that is a function of time for the second deflection angle and that takes into account that a temporal variation of the second deflection angle depends on the first deflection angle; and
causing the light source to emit the light beam in correspondence with the estimated scanning trajectory and image information.
